(19) United States
(12) Patent Application Publication
(10) Pub. No.: US 2026/0370222 A1
(43) Pub. Date: Nov. 19, 2026

(54) CONTROL CIRCUIT AND SEMICONDUCTOR DEVICE

(71) Applicant: FUJI ELECTRIC CO., LTD., Kanagawa (JP)

(72) Inventor: Daisuke ISOBE, Matsumoto-city (JP)

(21) Appl. No.: 19/578,896

(22) Filed: Mar. 26, 2026

(30) Foreign Application Priority Data
May 13, 2025 (JP) 2025-080781

(51) Int. Cl. H03K 17/082; G01R 31/28

(52) U.S. Cl. CPC H03K 17/0822; G01R 31/2853

(57) ABSTRACT

Provided is a control circuit that controls supply of electric power to a load circuit, comprising: a switching device connected in series with the load circuit; a short-circuit detection unit which detects whether the load circuit is in a short-circuit state and controls the switching device based on a detection result; a filter unit which stops control of the switching device performed by the short-circuit detection unit from a turn-on of the switching device until a set filter period elapses; and a period change unit which changes the filter period based on a state of at least one of the switching device or the load circuit.

### BACKGROUND

### 1. Technical Field

The present invention relates to the control circuit and the semiconductor device.

### 2. Related Art

Patent Document 1 discloses that the reset condition of the alarm signal is a condition that at least the protection operation stop condition, in which the first-come-first-served protection circuit detects that the protection operation is not necessary, is satisfied, and that the determination of the reset condition is performed within a fixed period of time of the pulse signal (see Claim 1 and the like). Patent document 2 discloses a device comprising "the initial charging unit provided to the DC link and having a switch and a charging resistor connected in parallel with the switch, wherein during an initial charging period before a motor drive start, the initial charging unit performs an initial charging with direct current flowing from the rectifying circuit through the charging resistor with the switch being opened so that the smoothing capacitor reaches the predetermined voltage" (see Claim 1 and the like).

Patent Document 1: International Publication No. 2012/137514

Patent Document 2: Japanese Patent Application Publication No. 2017-5973

### BRIEF DESCRIPTION OF THE DRAWINGS

FIG. 1 is a circuit diagram representing an example of the semiconductor device 400 according to a reference example.

FIG. 2A is a timing chart representing an operation example of the control circuit 10.

FIG. 2B is a timing chart representing another operation example of the control circuit 10.

FIG. 2C is a timing chart representing another operation example of the control circuit 10.

FIG. 2D is a timing chart representing another operation example of the control circuit 10.

FIG. 3 is a diagram representing an example of the semiconductor device 300 according to one embodiment of the present invention.

FIG. 4A is a timing chart representing an operation example of the control circuit 100.

FIG. 4B is a timing chart representing another operation example of the control circuit 100.

FIG. 5 is a diagram representing a configuration example of the period change unit 150.

FIG. 6 is a diagram representing an example of the filter unit 120.

FIG. 7A is a diagram representing the configuration example of the first extraction circuit 186-1.

FIG. 7B is a diagram representing the configuration example of the second extraction circuit 186-2.

FIG. 7C is a diagram representing the configuration example of the extraction circuit at the time of short-circuit release 197.

FIG. 8 is a diagram representing an operation example of the control circuit 100.

FIG. 9A is a timing chart representing another operation example of the control circuit 100.

FIG. 9B is a timing chart representing another operation example of the control circuit 100.

FIG. 9C is a timing chart representing another operation example of the control circuit 100.

### DESCRIPTION OF EXEMPLARY EMBODIMENTS

Hereinafter, the present invention will be described through embodiments of the invention, but the following embodiments do not limit the invention according to the claims. Further, not all of combinations of features described in the embodiments are essential to the solutions of the invention. Note that in the present specification and the diagrams, elements having substantially the same function and architecture are denoted with a same reference sign to omit duplicated descriptions, and illustrations of elements that are not directly related to the present invention will be omitted. Further, in one drawing, elements having the same functions and configurations are denoted by a representative reference sign, and other reference signs for the elements may be omitted.

When a term such as “same” or “equal” is used herein, it may encompass a case where an error due to a variation in manufacturing or the like is included. The error is, for example, within 10%.

In an electric circuit, when the positional relationship between elements such as electric elements is described, the description explains the position of the elements on the electrical path. The description does not limit the spatial position of the element unless expressly stated otherwise.

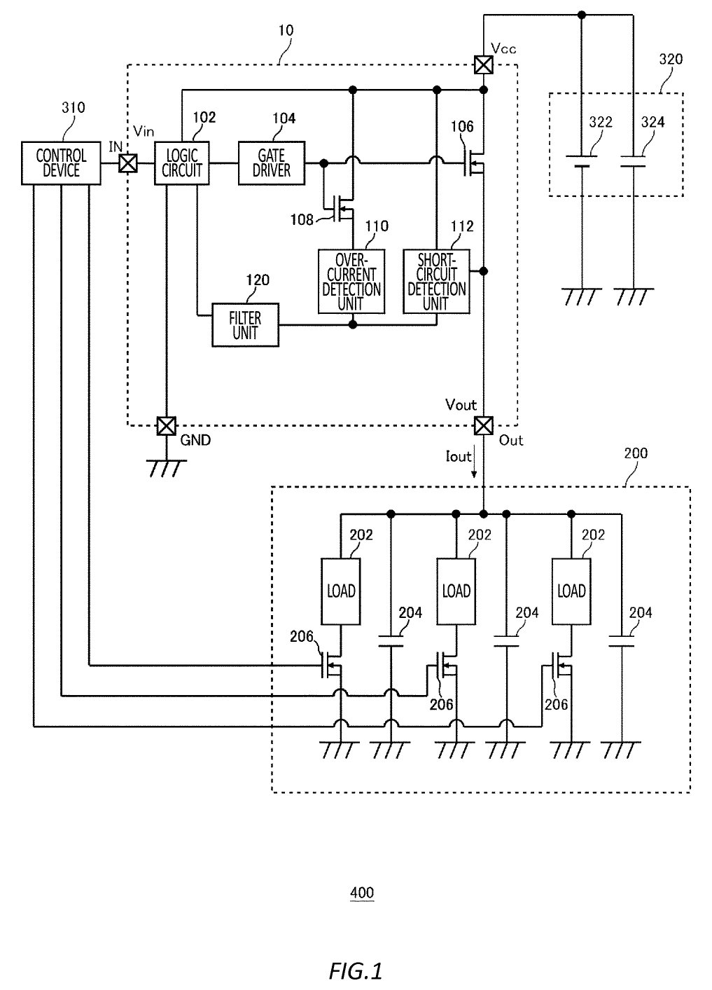

FIG. 1 is a circuit diagram representing an example of the semiconductor device 400 according to a reference example. The semiconductor device 400 is an electric circuit including a semiconductor element. The semiconductor device 400 is used, for example, in mobile bodies such as automobiles or in industrial robots in factories; however, the application of the semiconductor device 400 is not limited thereto.

The semiconductor device 400 includes the control circuit 10 and the load circuit 200. The semiconductor device 400 may further include one or both of the control device 310 and the power supply device 320. The control device 310 may be the microcomputer or the like. The control device 310 may control the equipment in which the semiconductor device 400 is provided. The power supply device 320 generates the power supply power for the semiconductor device 400. The power supply device 320 may have one or both of the direct current power supply 322 and a power storage circuit 324, such as a battery.

The load circuit 200 of this example includes one or more loads 202 and one or more load capacitors 204. The load circuit 200 may further include one or more switches 206. Each load 202 is supplied with electric power from the control circuit 10. The load 202 may be, for example, the motor or the like, and may also be another circuit element.

Each load capacitor 204 charges electric power from the control circuit 10. The load capacitor 204 may supply the charged electric power to the load 202. In this example, the load capacitor 204 is provided in one-to-one correspondence with the load 202. By providing the load capacitor 204, it is possible to suppress fluctuations in the voltage applied to the load 202.

Each switch 206 controls whether electric power is supplied to load 202. In this example, the switch 206 is provided in one-to-one correspondence with the load 202. The control device 310 may control each switch 206. Each switch in this specification is, for example, a power transistor such as the MOSFET or the IGBT. The control device 310 may apply the gate signal to the gate terminal of the switch 206.

The control circuit 10 controls the supply of electric power to the load circuit 200. The control circuit 10 of this example receives electric power from the power supply device 320 and supplies electric power to the load circuit 200. The control circuit 10 of this example has the input terminal IN, the power supply terminal Vcc, the output terminal Out, and the ground terminal GND.

The control signal Vin for controlling the switching device 106 is input to the input terminal IN. In this example, the control device 310 inputs the control signal Vin to the input terminal IN. The control signal Vin is the signal that defines the on period and the off period of the switching device 106. The control signal Vin may be the digital signal that indicates a first logic value (for example, H logic) in the on period and indicates a second logic value (for example, L logic) in the off period.

The power supply power is supplied to the power supply terminal Vcc. The power supply device 320 is connected to the power supply terminal Vcc of this example. The control circuit 10 controls whether at least part of the electric power supplied to the power supply terminal Vcc is supplied to the load circuit 200. The power supply power may be supplied to each element of the control circuit 10. The reference potential such as a ground potential is applied to the ground terminal GND. The reference potential may be applied to each element of the control circuit 10.

The load circuit 200 is connected to the output terminal Out. In this example, the voltage output from the output terminal Out to the load circuit 200 is defined as the output voltage Vout, and the current output from the output terminal Out to the load circuit 200 is defined as the output current Iout.

The control circuit 10 includes the switching device 106, the short-circuit detection unit 112, and the filter unit 120. The control circuit 10 may further include at least one of the logic circuit 102, the gate driver 104, or the overcurrent detection unit 110. In the example of FIG. 1, the control circuit 10 has all of the logic circuit 102, the gate driver 104, and the overcurrent detection unit 110.

The switching device 106 is connected in series with the load circuit 200. The switching device 106 of this example controls the supply of electric power from the power supply terminal Vcc to the output terminal Vout. The switching device 106 may be a transistor such as the MOSFET or the IGBT, in which the drain terminal (or collector terminal) is connected to the power supply terminal Vcc and the source terminal (or emitter terminal) is connected to the output terminal Out. In this example, when the switching device 106 is in the ON state, electric power is supplied from the power supply device 320 to the load circuit 200, and when the switching device 106 is in the off state, the supply of electric power to the load circuit 200 is shut down.

The logic circuit 102 and the gate driver 104 control switching of the switching device 106 based on the control signal Vin input to the input terminal IN. The logic circuit 102 outputs the signal corresponding to the control signal Vin to the gate driver 104 as Vgin. The logic circuit 102 may control whether to output the control signal Vgin to the gate driver 104. For example, when the state of at least one of the switching device 106 or the load circuit 200 becomes a predetermined state, the logic circuit 102 may stop the output of the control signal Vgin to the gate driver 104. In a case where, as an example, a load short-circuit state in which a reference potential or the like is applied to the output terminal Out occurs, the logic circuit 102 may stop the output of the control signal Vgin and may output a signal to the gate driver 104 to turn the switching device 106 into the off state.

The gate driver 104 outputs a signal corresponding to the input control signal Vgin. The gate driver 104 of this example applies the gate signal corresponding to the input control signal Vgin to the gate terminal of the switching device 106. The gate driver 104 may output the gate signal having an analog waveform corresponding to a logic value pattern of the control signal Vgin. Accordingly, the switching device 106 operates in response to the control signal Vgin.

The overcurrent detection unit 110 detects whether the output current Iout is in an overcurrent state, and controls the switching device 106 based on the detection result. The overcurrent detection unit 110 may detect whether the magnitude of the output current Iout is equal to or greater than the threshold voltage that is set, and the overcurrent detection unit 110 may detect whether the output current Iout in the case where the switching device 106 is in the ON state is an overcurrent. In this example, the control circuit 10 causes the overcurrent detection unit 110 to detect the overcurrent state based on the current flowing through the current sense element 108 in the case where the gate signal output from the gate driver 104 is at the H level. The current sense element 108 may be a transistor such as the MOSFET having a predetermined size ratio with respect to the switching device 106.

The overcurrent detection unit 110 may control the switching device 106 to the off state regardless of the logic value of the control signal Vin, in the case where the overcurrent state is detected. The overcurrent detection unit 110 may fix the switching device 106 in the off state until the overcurrent state is resolved. By such control, it is possible to protect the switching device 106 and the load circuit 200. The overcurrent detection unit 110 may fix the gate signal to the L level by notifying at least one of the logic circuit 102 or the gate driver 104 when the overcurrent state is detected.

The short-circuit detection unit 112 detects whether the load circuit 200 is in the short-circuit state, and controls the switching device 106 based on the detection result. In this example, the short-circuit state is a state in which the switching device 106 is in the ON state, and the magnitude of the output voltage Vout is smaller than the threshold voltage that is set. For example, when the reference potential is directly connected to the output terminal Out, even if the switching device 106 is in the ON state, the output voltage Vout hardly increases, and the large output current Iout flows.

The short-circuit detection unit 112 may control the switching device 106 to be in the off state regardless of the logic value of the control signal Vin, in the case where the short-circuit state is detected. The short-circuit detection unit 112 may fix the switching device 106 in the off state until the short-circuit state is resolved. By such control, it is possible to protect the switching device 106 and the load circuit 200. The short-circuit detection unit 112 may fix the gate signal to the L level by notifying at least one of the logic circuit 102 or the gate driver 104 when the short-circuit state is detected.

The filter unit 120 may stop control by the short-circuit detection unit 112 over the switching device 106 from the turn-on of the switching device 106 until the set filter period elapses. Furthermore, the filter unit 120 may stop control by the overcurrent detection unit 110 over the switching device 106 from the turn-on of the switching device 106 until the set filter period elapses. Accordingly, it is possible to prevent erroneous detection of the overcurrent state or the short-circuit state in the unstable state of the switching device 106 immediately after turn-on. The filter unit 120 may stop the operation of the short-circuit detection in the short-circuit detection unit 112 until the filter period elapses. In another example, the filter unit 120 may invalidate the short-circuit state that the short-circuit detection unit 112 has detected within the filter period. Similarly, the filter unit 120 may stop the operation of the overcurrent detection in the overcurrent detection unit 110 until the filter period elapses. In other examples, the filter unit 120 may invalidate the overcurrent state detected by the overcurrent detection unit 110 within the filter period.

For example, even if the load circuit 200 or the like is normal, immediately after the turn-on of the switching device 106, there may be a case where the large current flows in order to charge the load capacitor 204. By providing a filter period, it is possible to prevent such a large current from being erroneously detected as an overcurrent. Further, even if the load circuit 200 is not in a short-circuit state, since the output voltage Vout is at the L level immediately after turn-on of the switching device 106, by providing a filter period, it is possible to prevent erroneous detection of the short-circuit state immediately after turn-on of the switching device 106.

However, in the case where the filter period is not appropriately set, erroneous detection of the overcurrent state and the short-circuit state may occur. For example, in a case where the load capacitor 204 remains charged even after the filter period has elapsed, there is a risk of erroneous detection of the overcurrent state or the short-circuit state. Although it is conceivable to set the capacitance of the load capacitor 204 so that the charging of the load capacitor 204 ends within the filter period, in this case, the capacitance of the load capacitor 204 that can be used is limited.

For example, the chargeable capacitance of the load capacitor 204 is determined in response to the product of the upper limit value of the output current Iout and the length of the filter period. The upper limit value of the output current Iout is set, for example, by the current limiting function in the control circuit 10. The output current Iout having the upper limit value is referred to as the maximum output current. The safe operating area of the switching device 106 is affected by the voltage applied between the source and drain of the switching device 106, the maximum output current, and the duration during which current flows. The respective parameters of the control circuit 10 are set so that the switching device 106 can operate safely.

In the reference example, the filter period is set, for example, according to the voltage and the current of the switching device 106 at the time of a load short circuit, which is a worst case. At the time of a load short circuit, the voltage applied to the switching device 106 is high, and a large current flows. Even in such a case, it is necessary to set the filter period in order to prevent the voltage and the current of the switching device 106 from exceeding the safe operating area. After the filter period elapses, since the current is shut down in response to the detection of the overcurrent and the short-circuit, it is possible to prevent the switching device 106 from operating beyond the safe operating area.

Even in the normal state which is not the load short-circuit state, the large current flows to charge the load capacitor 204. However, in the normal state, since the voltage of the load capacitor 204 gradually increases, the voltage applied to the switching device 106 gradually decreases. Therefore, in the normal state, even if the filter period is longer than at the time of the load short circuit, it is possible to operate the switching device 106 within the safe operating area. On the other hand, in the reference example, even in the case of the normal state, the same filter period as at the time of the load short circuit is applied. As described above, the chargeable capacitance of the load capacitor 204 is determined in response to the filter period in the normal state. Therefore, in the reference example, it is difficult to use the load capacitor 204 having a large capacitance.

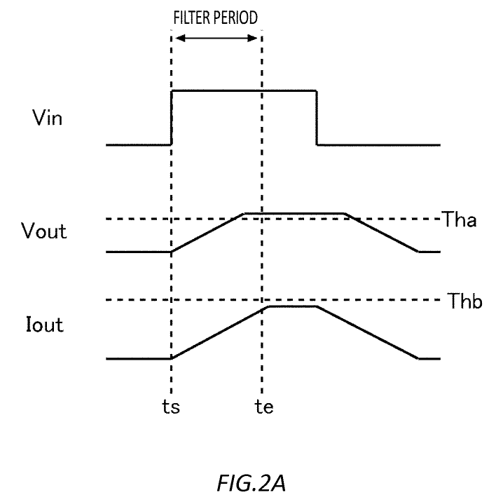

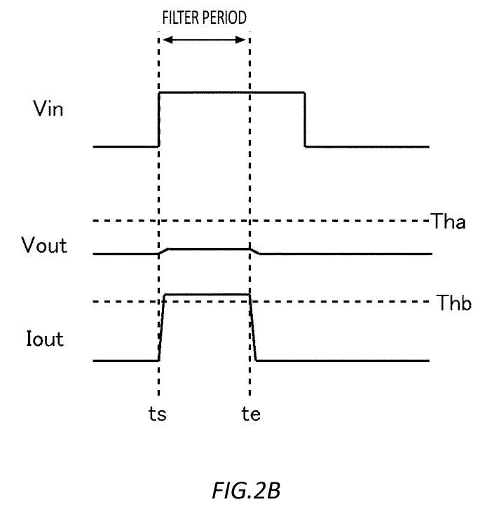

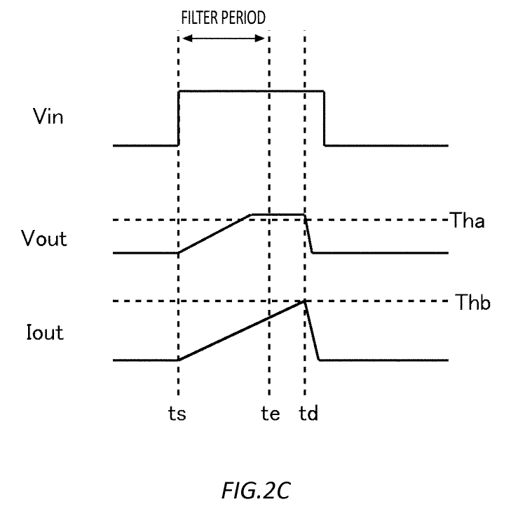

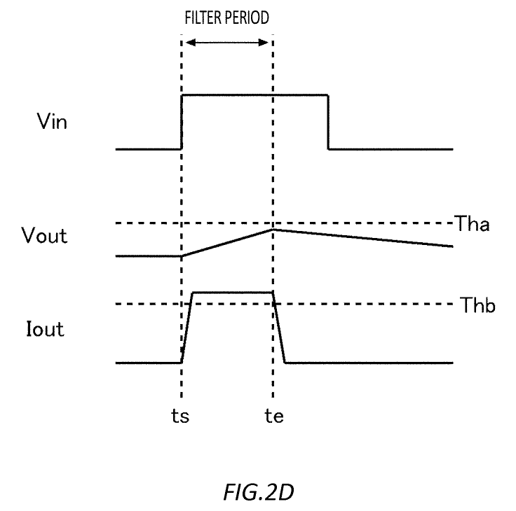

FIG. 2A is a timing chart representing an operation example of the control circuit 10. FIG. 2A represents an example of time waveforms of the control signal Vin, the output voltage Vout, and the output current Iout in the case where the load circuit 200 which does not have the load capacitor 204 is connected.

When the control signal Vin transitions to H logic at time ts, the switching device 106 turns on. When the switching device 106 turns on, the output voltage Vout and the output current Iout increase.

The filter unit 120 detects the time te at which the filter period elapses, with time ts as a starting point. The filter period is preset in the filter unit 120. In this example, the filter period is set according to the characteristics of the circuit elements provided in the filter unit 120. For example, the filter unit 120 charges the capacitor with a constant current, using the time ts as a starting point. The filter unit 120 may determine that the filter period has elapsed in a case where the voltage of the capacitor has reached the predetermined value. In this case, the length of the filter period can be set, for example, based on the magnitude of the constant current and the capacitance value of the capacitor.

The short-circuit detection unit 112 determines whether the load circuit 200 is in the short-circuit state. The short-circuit detection unit 112 of this example determines that the short-circuit state exists when the output voltage Vout does not exceed the short-circuit determination voltage Tha after the filter period has elapsed (after time te). In this example, after time te, which is when the filter period has elapsed, since the output voltage Vout exceeds the short-circuit determination voltage Tha, the short-circuit detection unit 112 determines that the short-circuit state is not present. Note that the short-circuit detection unit 112 may detect the short-circuit state by comparing the output voltage Vout with the short-circuit determination voltage Tha in a state where the switching device 106 is controlled to be in the ON state (in this example, where the control signal Vin is at H logic). Therefore, as represented in FIG. 2A, even if the output voltage Vout falls below the short-circuit determination voltage Tha while the control signal Vin is in the L logic state, the short-circuit detection unit 112 does not determine that the short-circuit state exists.

The overcurrent detection unit 110 determines whether the output current Iout is in the overcurrent state. In this example, the overcurrent detection unit 110 determines that the overcurrent state exists when the output current Iout exceeds the overcurrent judgment value Thb after the filter period has elapsed (after time te). In this example, after time te, which is when the filter period has elapsed, since the output current Iout does not exceed the overcurrent judgment value Thb, the overcurrent detection unit 110 determines that the overcurrent state is not present. The overcurrent detection unit 110 may detect the overcurrent state in a state where the switching device 106 is controlled to be in the ON state (in this example, the control signal Vin is in the H logic state).

FIG. 2B is a timing chart representing another operation example of the control circuit 10. In FIG. 2B, an example of time waveforms of the control signal Vin, the output voltage Vout, and the output current Iout in the short-circuit state is represented.

When the switching device 106 turns on in the short-circuit state, the output current Iout increases significantly, whereas the output voltage Vout does not increase so much. In this example, even after the filter period elapses, the output voltage Vout does not exceed the short-circuit determination voltage Tha. Therefore, the short-circuit detection unit 112 determines that the short-circuit state exists and fixes the switching device 106 in the off state. Accordingly, the output current Iout is shut down, and the switching device 106 and the load circuit 200 and the like can be protected.

FIG. 2C is a timing chart representing another operation example of the control circuit 10. FIG. 2C illustrates an example of the time waveforms of the control signal Vin, the output voltage Vout, and the output current Iout in the case where the overcurrent state is detected after the elapse of the filter period.

In this example, when the switching device 106 turns on, the output voltage Vout and the output current Iout increase. The output voltage Vout becomes greater than the short-circuit determination voltage Tha within the filter period. Therefore, the short-circuit detection unit 112 determines that the short-circuit state does not exist. On the other hand, in this example, the output current Iout becomes greater than the overcurrent judgment value Thb at time td after the elapse of the filter period. The overcurrent detection unit 110 detects the overcurrent state at time td, and fixes the switching device 106 in the off state. Accordingly, the output current Iout is shut down, and the switching device 106 and the load circuit 200 and the like can be protected.

FIG. 2D is a timing chart representing another operation example of the control circuit 10. FIG. 2D represents an example of time waveforms of the control signal Vin, the output voltage Vout, and the output current Iout in the case where the load circuit 200 which has the load capacitor 204 is connected.

In this example, when the switching device 106 turns on, the output voltage Vout and the output current Iout increase. In this example, the large output current Iout is flowing in order to charge the load capacitor 204. In this example, the charging of the load capacitor 204 has not ended within the filter period, and the output voltage Vout does not exceed the short-circuit determination voltage Tha at the time te. Therefore, the short-circuit detection unit 112 makes an erroneous determination that the short-circuit state exists at time te. Further, at time te, the output current Iout is greater than the overcurrent judgment value Thb. Therefore, the overcurrent detection unit 110 makes an erroneous determination that the overcurrent state exists at time te.

By reducing the capacitance of the load capacitor 204 to such an extent that the completion of charging occurs within the filter period, it is possible to avoid such erroneous detection. However, the capacitance of the load capacitor 204 that can be used for the load circuit 200 is limited.

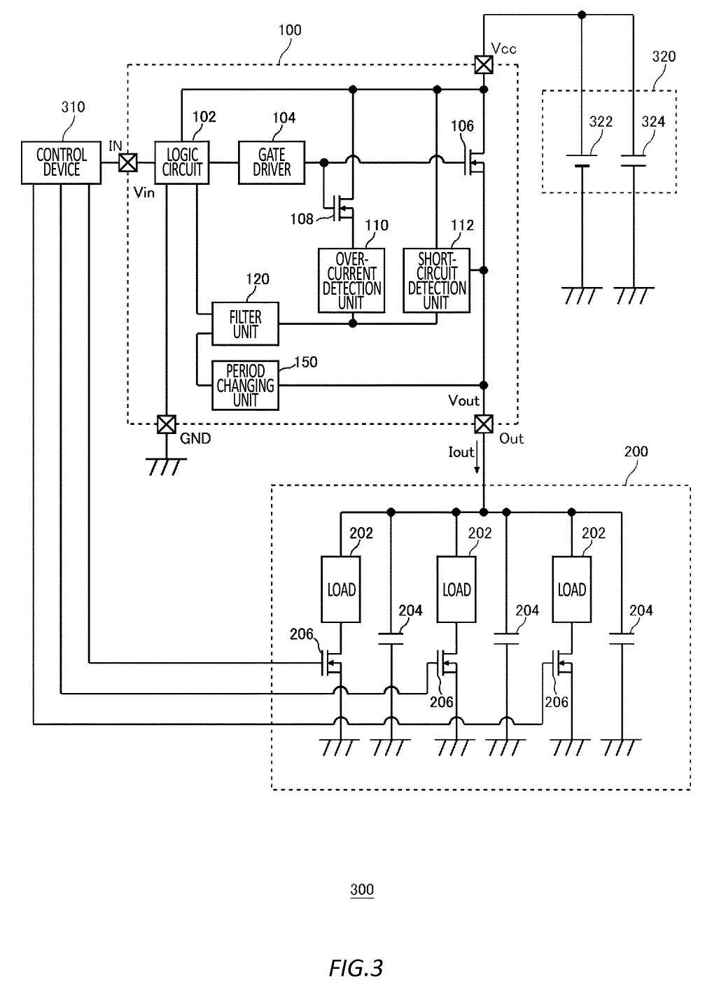

FIG. 3 is a diagram representing an example of the semiconductor device 300 according to one embodiment of the present invention. The semiconductor device 300 of this example includes the control circuit 100 instead of the control circuit 10 in comparison with the components of the semiconductor device 400. Other components are similar to the semiconductor device 400.

The control circuit 100 further comprises the period change unit 150 in addition to the components of the control circuit 10. The components other than the period change unit 150 are similar to those of the control circuit 10. Further, in this example, the length of the filter period in the filter unit 120 is variable. The period change unit 150 changes the filter period in the filter unit 120, based on the state of at least one of the switching device 106 or the load circuit 200.

The state of the switching device 106 may be determined by at least one of the voltage at each terminal of the switching device 106, the current flowing through each terminal, and the temperature of each terminal, for example. The state of the switching device 106 may be determined from the comparison result between these parameters and the set reference value.

The state of the load circuit 200 may be determined by at least one of the voltage in each element of the load circuit 200, the current flowing through each element, or the temperature of each element, for example. The state of the load circuit 200 may be determined based on these parameters and the comparison result with the reference value that is set.

By changing the filter period based on the state of at least one of the switching device 106 or the load circuit 200, it is possible to reduce erroneous detection of the overcurrent state or the short-circuit state. For example, by extending the filter period in the case where the load capacitor 204 is charged, it is possible to reduce erroneous detection of the overcurrent state or the short-circuit state described in FIG. 2D. However, the state of at least one of the switching device 106 or the load circuit 200 is not limited to the charging state of the load capacitor 204. By appropriately adjusting the filter period in response to various states, it is possible to reduce erroneous detection of the overcurrent state or the short-circuit state. The changing of the filter period may be the extension of the filter period or the shortening of the filter period.

The period change unit 150 of this example detects the state of at least one of the switching device 106 or the load circuit 200 within the filter period. The period change unit 150 determines whether to extend the filter period based on the detected state. By dynamically extending the filter period within the filter period, it is possible to appropriately set the filter period according to the state of the switching device 106 or the load circuit 200 during the filter period.

The period change unit 150 determines whether the load circuit 200 is in the charging state in which the load capacitor 204 included in the load circuit 200 is being charged, based on the state of at least one of the switching device 106 or the load circuit 200, and may extend the filter period in the case of the charging state. By such control, it is possible to easily reduce the erroneous detection of the overcurrent state or the short-circuit state described in FIG. 2D. Note that the period change unit 150 may perform a process to shorten the filter period instead of performing a process to extend the filter period. For example, the long filter period may be set in advance, and in a case where it is determined that the load circuit 200 is not in a charging state, the filter period may be shortened. Even with such a process, an effect similar to that of extending the filter period can be obtained.

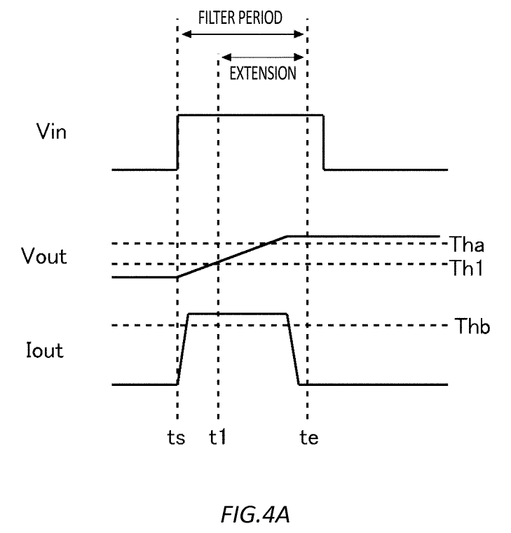

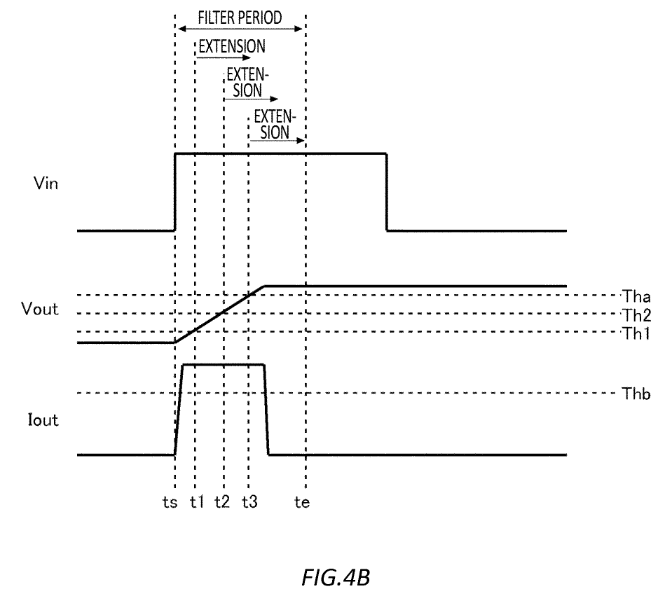

FIG. 4A is a timing chart representing an operation example of the control circuit 100. FIG. 4A represents an example of time waveforms of the control signal Vin, the output voltage Vout, and the output current Iout in the case where the load circuit 200 which has the load capacitor 204 is connected.

Similarly to the example of FIG. 2D, when the switching device 106 turns on, the output voltage Vout and the output current Iout increase. In this example, the large output current Iout is flowing in order to charge the load capacitor 204.

The period change unit 150 of this example extends the filter period based on the output voltage Vout applied to the load circuit 200. The period change unit 150 extends the filter period when the output voltage Vout exceeds the first threshold voltage Th1 within the filter period. That is, the period change unit 150 of this example monitors whether the output voltage Vout exceeds the first threshold voltage Th1 while the filter period continues. When the output voltage Vout exceeds the first threshold voltage Th1, the period change unit 150 extends the filter period by the predetermined extension period while the filter period continues. Accordingly, it is possible to extend the filter period without interrupting the filter period. The length of the extension period may be preset in the period change unit 150 or the filter unit 120.

The length of the extension period may be the same as the length of the initial filter period that has not been extended. In this case, the filter period having a certain length may be set in the filter unit 120. The period change unit 150 extends the filter period by starting a new filter period with a certain length during the filter period of the certain length. In another example, the extension period may be shorter than the initial filter period or may be longer than the initial filter period. The certain length may be set so that the voltage and the current applied to the switching device 106 are within the safe operating area even at the time of the load short circuit.

The first threshold voltage Th1 may be generated by the period change unit 150. The period change unit 150 may generate the first threshold voltage Th1 by using the voltage generated by a circuit such as a diode. The first threshold voltage Th1 can be preset by adjusting the characteristics of the circuit such as the diode. As represented in FIG. 4A, the first threshold voltage Th1 is lower than the short-circuit determination voltage Tha. The first threshold voltage Th1 may have the magnitude that is half of the short-circuit determination voltage Tha, may be smaller than half of the short-circuit determination voltage Tha, or may be greater than half of the short-circuit determination voltage Tha.

In the example of FIG. 4A, at time t1 within the initial filter period, the output voltage Vout is greater than the first threshold voltage Th1. The period change unit 150 causes the filter unit 120 to start the new filter period at time t1. Accordingly, it is possible to extend the filter period. In the case where the load capacitor 204 is charged, the output voltage Vout gradually increases. Therefore, by monitoring the increase of the output voltage Vout, it is possible to determine whether the load capacitor 204 is being charged. In this example, although the increase in the output voltage Vout is monitored by using the first threshold voltage Th1, the increase in the output voltage Vout may be monitored by using a larger number of threshold voltages Th, and the increase in the output voltage Vout may be monitored by another method. In the case where a predetermined amount of increase in the output voltage Vout is detected, by extending the filter period, it is possible to complete charging of the load capacitor 204 within the filter period. Accordingly, it is possible to suppress erroneous detection of the overcurrent state or the short-circuit state, and it is also possible to use the relatively large load capacitor 204.

FIG. 4B is a timing chart representing another operation example of the control circuit 100. FIG. 4B represents an example of time waveforms of the control signal Vin, the output voltage Vout, and the output current Iout in the case where the load circuit 200 which has the load capacitor 204 is connected.

The control circuit 100 of this example compares the first threshold voltage Th1 and the second threshold voltage Th2 with the output voltage Vout. The second threshold voltage Th2 is greater than the first threshold voltage Th1 and less than the short-circuit determination voltage Tha. The control circuit 100 extends the filter period each time the output voltage Vout exceeds each threshold voltage. The length of each extension period may be the same or may be different. The extension period in this example is the same as the length of the initial filter period that has not been extended, but is not limited thereto. The extension period in this example indicates a period until the filter period ends, using each time t1, t2, and t3 at which the extension is started as a starting point.

By setting a plurality of the threshold voltages Th, it is possible to improve the resolution of detection of an increase in the output voltage Vout. Therefore, the number of times or the resolution of timing for extending the filter period is improved, and even if the extension period per time is shortened, the filter period can be appropriately extended. By shortening the extension period for one time, it is possible to reduce the circuit scale of the filter unit 120. In addition, it is possible to suppress the filter period from being excessively extended, and it is possible to reduce the overlooking of the detection of the overcurrent state or the short-circuit state.

As represented in FIG. 4B, the period change unit 150 may extend the filter period even in the case where the output voltage Vout exceeds the short-circuit determination voltage Tha within the filter period. That is, within the filter period, the short-circuit determination voltage Tha may function as the threshold voltage Th for the determination of extension of the filter period. Accordingly, it is possible to increase the number of the threshold voltages Th and further shorten the extension period.

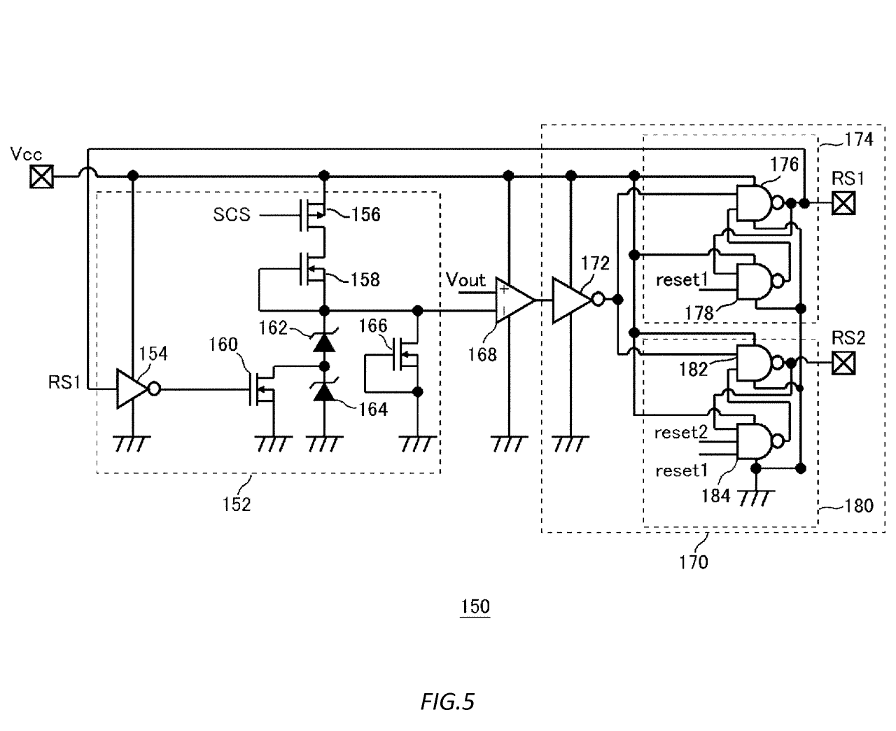

FIG. 5 is a diagram representing a configuration example of the period change unit 150. The period change unit 150 of this example includes the threshold voltage generation unit 152, the voltage comparison unit 168, and the reset unit 170. The threshold voltage generation unit 152 generates one or more threshold voltages including the first threshold voltage Th1. The threshold voltage generation unit 152 generates the first threshold voltage Th1 and the second threshold voltage Th2, similarly to the example in FIG. 4B. The threshold voltage generation unit 152 may generate the first threshold voltage Th1 and the second threshold voltage Th2 sequentially. The threshold voltage generation unit 152 of this example generates the second threshold voltage Vth2 when the output voltage Vout exceeds the first threshold voltage Vth1 after generating the first threshold voltage Th1.

The voltage comparison unit 168 compares the output voltage Vout and each threshold voltage Th generated by the threshold voltage generation unit 152. The voltage comparison unit 168 of this example compares the first threshold voltage Th1 initially generated by the threshold voltage generation unit 152 and the output voltage Vout. As represented in FIGS. 4A, and 4B , when the output voltage Vout becomes greater than the first threshold voltage Th1, the filter period is extended. Further, in the case where the output voltage Vout becomes greater than the first threshold voltage Th1, the threshold voltage generation unit 152 generates the second threshold voltage Th2 that is greater than the first threshold voltage Th1. As represented in FIG. 4B, in the case where the output voltage Vout becomes greater than the second threshold voltage Th2 within the filter period after extension, the filter period is extended again.

The threshold voltage generation unit 152 of this example includes the first diode 162, the second diode 164, and the threshold switching unit 160. The threshold voltage generation unit 152 may further include at least one of the inverter 154, the switch 156, the resistance unit 158, or the resistance unit 166.

The first diode 162 and the second diode 164 of this example are Zener diodes that generate a constant voltage. The first diode 162 and the second diode 164 are connected in series between the power supply terminal Vcc and the reference potential. The cathode terminal of the first diode 162 is connected to the negative input terminal of the voltage comparison unit 168. The second diode 164 is provided between the first diode 162 and the reference potential. The cathode terminal of the second diode 164 is connected to the anode terminal of the first diode 162. The anode terminal of the second diode 164 is connected to the reference potential.

The threshold switching unit 160 switches whether to connect a node between the first diode 162 and the second diode 164 to the reference potential, in response to the first reset signal RS1. The first reset signal RS1 is the signal indicating that the filter period is to be extended in response to the output voltage Vout exceeding the first threshold voltage Th1. The threshold switching unit 160 of this example is a transistor such as the MOSFET in which a signal corresponding to the first reset signal RS1 is input to the gate terminal.

The threshold switching unit 160 enters the on state in the state where the output voltage Vout does not exceed the first threshold voltage Th1 (RS1 = L), and connects the anode terminal of the first diode 162 to the reference potential. In this case, the voltage of the cathode terminal of the first diode 162 becomes a voltage with respect to the reference potential, which is generated by one first diode 162. The voltage is used as the first threshold voltage Th1.

The threshold switching unit 160 enters the off state when the output voltage Vout exceeds the first threshold voltage Th1 (RS1 = H), and disconnects the anode terminal of the first diode 162 from the reference potential. In this case, the voltage of the cathode terminal of the first diode 162 becomes the sum of the voltages generated by the first diode 162 and the second diode 164 with respect to the reference potential. The voltage is used as the second threshold voltage Th2.

The inverter 154 inverts the first reset signal RS1 and inputs the first reset signal RS1 to the gate terminal of the threshold switching unit 160. The first reset signal RS1 of this example is a signal that is at L logic in a state where the output voltage Vout does not exceed the first threshold voltage Th1, and is at H logic in a state where the output voltage Vout exceeds the first threshold voltage Th1. In this case, by inverting the first reset signal RS1 by the inverter 154, it is possible to switch between the first threshold voltage Th1 and the second threshold voltage Th2 as described above.

The resistance unit 166 is provided between the cathode terminal of the first diode 162 and the reference potential. The resistance unit 166 of this example is the depletion-type MOSFET in which the gate terminal and the source terminal are short-circuited, but another resistor element may also be used.

The switch 156 and the resistance unit 158 are provided in series between the power supply terminal Vcc and the cathode terminal of the first diode 162. In this example, the switch 156 is disposed between the power supply terminal Vcc and the resistance unit 158; however, the arrangement of the switch 156 and the resistance unit 158 may be reversed. The resistance unit 158 of this example is the depletion-type MOSFET in which the gate terminal and the source terminal are short-circuited, but another resistor element may also be used.

The switch 156 controls whether to allow the current from the power supply terminal Vcc to flow through the resistance unit 158 in response to the short-circuit signal SCS. The short-circuit signal SCS is the signal indicating whether the output voltage Vout has exceeded the short-circuit determination voltage. The short-circuit signal SCS may be generated by the short-circuit detection unit 112. The short-circuit signal SCS in this example is a signal which indicates H logic in the case where the output voltage Vout exceeds the short-circuit determination voltage Tha, and indicates L logic in the case where the output voltage Vout does not exceed the short-circuit determination voltage. That is, the short-circuit signal SCS indicates L logic when the short-circuit state is detected, and indicates H logic in the case where the short-circuit state is not detected.

In this example, the switch 156 enters the ON state in the case where the output voltage Vout does not exceed the short-circuit determination voltage, and connects the resistance unit 158 to the power supply terminal Vcc. Accordingly, the cathode terminal of the first diode 162 is connected to the power supply terminal Vcc via the resistance unit 158. As a result, the threshold voltage generation unit 152 generates the first threshold voltage Th1 or the second threshold voltage Th2, and outputs the first threshold voltage Th1 or the second threshold voltage Th2 to the voltage comparison unit 168.

In the case where the output voltage Vout exceeds the short-circuit determination voltage Tha, the switch 156 of this example enters the off state, and the resistance unit 158 is disconnected from the power supply terminal Vcc. Accordingly, the threshold voltage generation unit 152 outputs the low voltage lower than the output voltage Vout to the voltage comparison unit 168. The low voltage may be lower than the short-circuit determination voltage Tha, may be lower than the second threshold voltage Th2, and may also be lower than the first threshold voltage Th1. In this example, the low voltage is the reference potential (0V). In this example, when the switch 156 becomes an off state, the reference potential is applied to the voltage comparison unit 168 via the resistance unit 166. By such an operation, in a case where it is detected that the short-circuit state is not present, the threshold voltage output from the threshold voltage generation unit 152 can be initialized. Accordingly, after the determination of the short-circuit state, the control circuit 100 transitions to the normal operation.

The reset unit 170 resets the filter period in the filter unit 120 and starts the new filter period in response to the comparison result in the voltage comparison unit 168. The filter unit 120 of this example generates the elapsed signal indicating the elapsed time from the start of the filter period, and when the elapsed signal indicating the elapsed time is in a predetermined state, the filter unit 120 determines that the filter period has ended. For example, the filter unit 120 may start charging the capacitor with the start of the filter period and may use the voltage of the capacitor as the elapsed signal. When the voltage of the elapsed signal exceeds the predetermined value, it can be determined that the filter period has ended. For example, the reset unit 170 may reset the measurement of the filter period by discharging the capacitor of the filter unit 120 and start a new measurement of the filter period.

The reset unit 170 of this example includes the first latch unit 174 and the second latch unit 180. The reset unit 170 may further include the inverter 172. The first latch unit 174 generates the first reset signal RS1 that resets the filter period when the output voltage Vout exceeds the first threshold voltage Th1 and maintains the first reset signal RS1. The second latch unit 180 generates the second reset signal RS2 that resets the filter period when the output voltage Vout exceeds the second threshold voltage Th2 and maintains the second reset signal RS2.

The inverter 172 inverts the signal output from the voltage comparison unit 168. The voltage comparison unit 168 of this example outputs H logic when the output voltage Vout is greater than the input threshold voltage Th, and outputs L logic when the output voltage Vout is less than the input threshold voltage Th. In this example, the inverter 172 outputs L logic when the output voltage Vout is greater than the threshold voltage Th, and outputs H logic when the output voltage Vout is less than the threshold voltage Th.

The first latch unit 174 of this example has the NAND circuit 176 and the NAND circuit 178. The output of the inverter 172 and the output of the NAND circuit 178 are input to the NAND circuit 176. The output of the NAND circuit 176 is used as the first reset signal RS1.

The output of the NAND circuit 176 and the first signal reset 1 are input to the NAND circuit 178. The first signal reset 1 is the signal indicating L logic for a very short constant period of time in the case where the control signal Vin transitions from L logic to H logic.

In this example, when the output voltage Vout exceeds the first threshold voltage Th1, the output of the inverter 172 becomes the L logic. In this case, the output of the NAND circuit 176 becomes H logic, and the first reset signal RS1 becomes H logic.

When the output voltage Vout becomes smaller than the first threshold voltage Th1, the output of the inverter 172 becomes the H logic. Even in this case, the output of the NAND circuit 176 is maintained at H logic until the output of the NAND circuit 178 transitions from L logic to H logic. In this state, when the control signal Vin transitions from L logic to H logic, the first signal reset 1 transitions to L logic, and the output of the NAND circuit 178 transitions to the H logic. Accordingly, the first reset signal RS1 transitions to the L logic. That is, the first latch unit 174 outputs the first reset signal RS1 of H logic from when the output voltage Vout exceeds the first threshold voltage Th1 until the control signal Vin transitions from the L logic to the H logic.

The second latch unit 180 of this example has the NAND circuit 182 and the NAND circuit 184. The output of the inverter 172 and the output of the NAND circuit 184 are input to the NAND circuit 182. The output of the NAND circuit 182 is used as the second reset signal RS2.

The output of the NAND circuit 182, the first signal reset 1, and the second signal reset 2 are input to the NAND circuit 184. The NAND circuit 184 outputs L logic when all three inputs are H logic, and outputs H logic in other cases. The second signal reset 2 is the signal that indicates L logic for a very short fixed period of time in the case where the output voltage Vout becomes greater than the first threshold voltage Th1, in order to reset the filter period.

In this example, when the output voltage Vout exceeds the second threshold voltage Th2, the output of the inverter 172 becomes the L logic. In this case, the output of the NAND circuit 182 becomes H logic, and the second reset signal RS2 becomes H logic.

When the output voltage Vout becomes smaller than the second threshold voltage Th2, the output of the inverter 172 becomes the H logic. Even in this case, the output of the NAND circuit 184 is maintained at H logic until the output of the NAND circuit 182 transitions from L logic to H logic. In this state, when the control signal Vin transitions from L logic to H logic, the first signal reset 1 transitions to L logic, and the output of the NAND circuit 184 transitions to the H logic. Accordingly, the second reset signal RS2 transitions to the L logic. That is, the second latch unit 180 outputs the second reset signal RS2 of H logic from when the output voltage Vout exceeds the second threshold voltage Th2 until the control signal Vin transitions from the L logic to the H logic.

Even in the case where the output voltage Vout exceeds the first threshold voltage Th1, the output of the NAND circuit 182 becomes H logic, and the second reset signal RS2 becomes H logic. However, in this case, the filter period is reset by the first reset signal RS1, and the second signal reset 2 becomes the L logic. Accordingly, in the case where the output voltage Vout exceeds the first threshold voltage Th1, the second reset signal RS2 becomes the H logic only for a very short period, and after the lapse of the very short period, the second reset signal RS2 returns to the L logic.

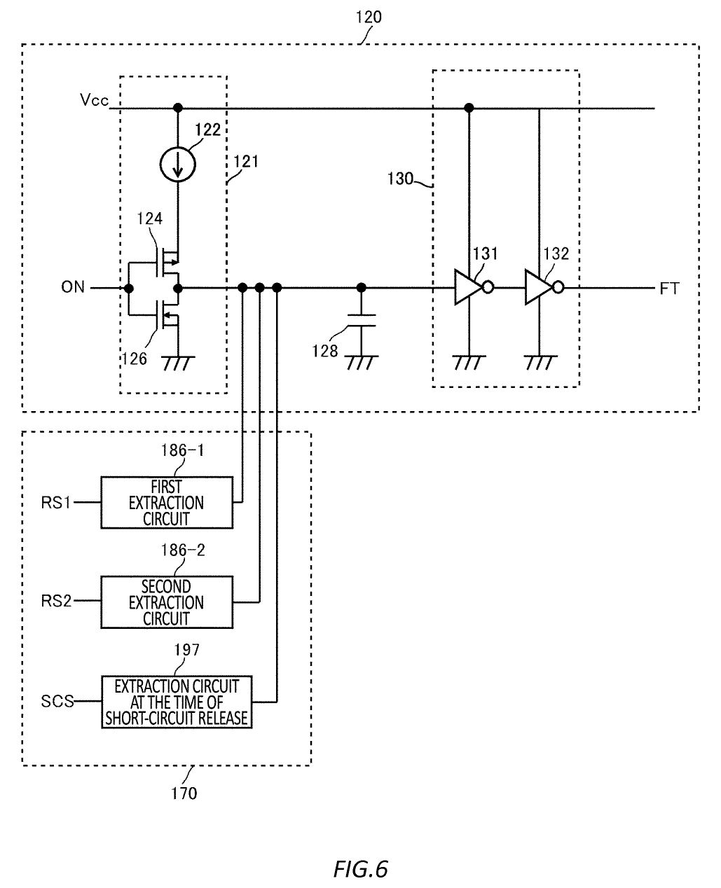

FIG. 6 is a diagram representing an example of the filter unit 120. FIG. 6 represents, in addition to the components of the filter unit 120, some components of the reset unit 170. The filter unit 120 includes the filter capacitor 128, the charging unit 121, and the period determination unit 130.

The filter capacitor 128 is provided between the charging unit 121 and the reference potential. The filter capacitor 128 is charged and discharged by the charging unit 121.

The charging unit 121 starts charging the filter capacitor 128 in response to the switching device 106 being turned on. The charging unit 121 of this example includes the current source 122, the transistor 124, and the transistor 126. The current source 122 is provided between the power supply terminal Vcc and the transistor 124, and generates the charging current for charging the filter capacitor 128.

The transistor 124 and the transistor 126 are provided in series between the current source 122 and the reference potential. The transistor 124 enters the ON state when the turn-on signal ON is L logic, and charges the filter capacitor 128 with the charging current. The turn-on signal ON may be the signal that becomes L logic when the switching device 106 is turned on. The transistor 126 enters the ON state when the turn-on signal ON is at H logic, and discharges the filter capacitor 128.

The period determination unit 130 determines that the filter period has ended when the voltage of the filter capacitor 128 exceeds the filter threshold voltage after the switching device 106 is turned on. The period determination unit 130 of this example includes the inverter 131 and the inverter 132. The voltage of the filter capacitor 128 is applied to the inverter 131. When the voltage of the filter capacitor 128 exceeds the threshold voltage of the inverter 131, the output of the inverter 131 transitions from the H logic to the L logic. The inverter 132 inverts the output of the inverter 131 and outputs the result as the period determination signal FT. The period determination signal FT in this example is the signal that indicates H logic in the case where the filter period has ended, and indicates L logic during the filter period. The period determination signal FT may be supplied to the overcurrent detection unit 110 and the short-circuit detection unit 112. The overcurrent detection unit 110 and the short-circuit detection unit 112 may detect the overcurrent state and the short-circuit state in response to the period determination signal FT.

In this example, the length of the filter period in the case where no extension is performed is determined by the current value of the current source 122, the capacitance of the filter capacitor 128, and the threshold voltage of the inverter 131. In this example, the reset unit 170 resets the filter period, during the filter period, by discharging the charged electric charge of the filter capacitor 128 for a fixed period of time. Accordingly, it is possible to initialize the voltage of the filter capacitor 128 and start the new filter period.

The reset unit 170 of this example includes the first extraction circuit 186-1, the second extraction circuit 186-2, and the extraction circuit at the time of short-circuit release 197. The first extraction circuit 186-1 extracts the electric charge of the filter capacitor 128 for the preset period in response to the first reset signal RS1. The second extraction circuit 186-2 extracts the electric charge of the filter capacitor 128 for the preset period in response to the second reset signal RS2. The extraction circuit at the time of short-circuit release 197-1 extracts the electric charge of the filter capacitor 128 for the preset period in response to the short-circuit signal SCS. As described above, the short-circuit signal SCS is the signal indicating that the output voltage Vout has exceeded the short-circuit determination voltage Tha.

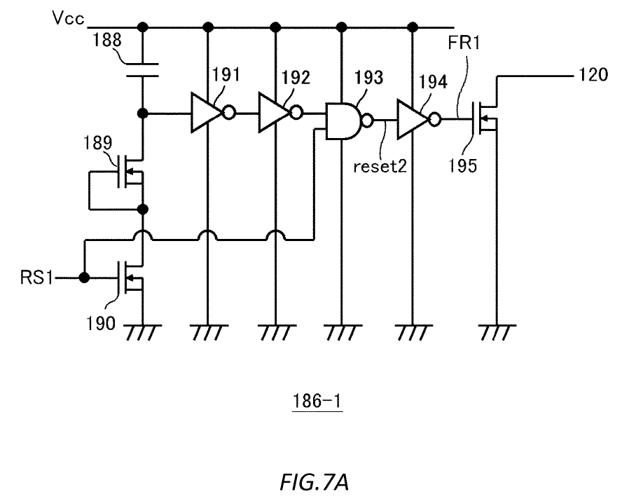

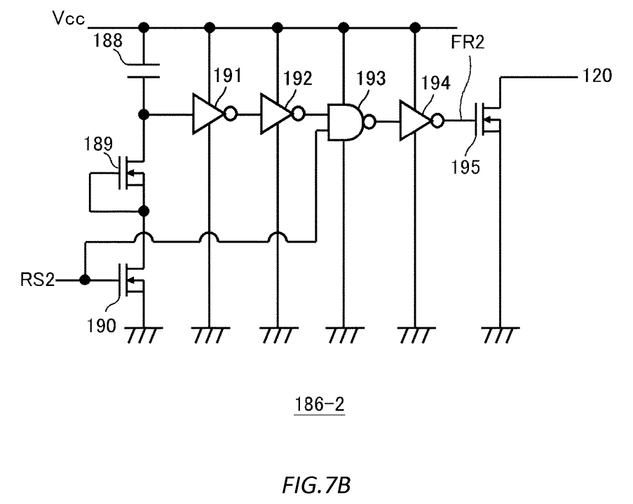

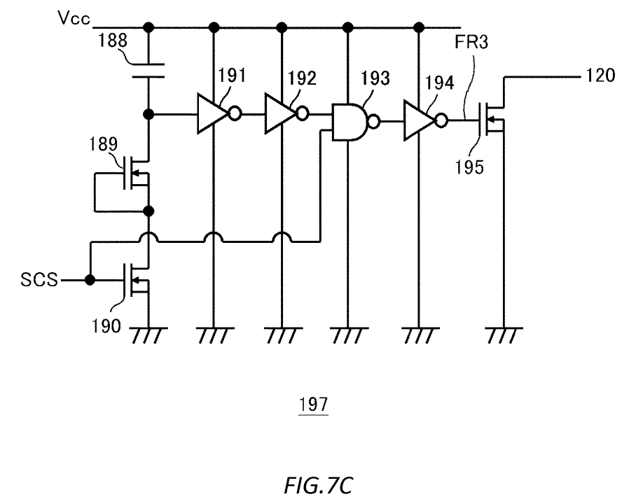

FIG. 7A is a diagram representing the configuration example of the first extraction circuit 186-1. The first extraction circuit 186-1 includes the capacitor 188, the resistance unit 189, the switch 190, the inverter 191, the inverter 192, the NAND circuit 193, the inverter 194, and the switch 195.

The capacitor 188 is provided between the power supply terminal Vcc and the resistance unit 189, and is charged by the current from the power supply terminal Vcc. The resistance unit 189 is provided between the capacitor 188 and the switch 190. The resistance unit 189 may include the depletion-type MOSFET, similarly to the resistance unit 158 and the like, and may also be another resistor element.

The switch 190 is provided between the resistance unit 189 and the reference potential. The switch 190 of this example is the MOSFET to which the first reset signal RS1 is input at the gate terminal. The switch 190 enters an ON state in the case where the first reset signal RS1 is at H logic, and charges the capacitor 188.

The signal at the connection point between the capacitor 188 and the resistance unit 189 is input to the inverter 191. The output of the inverter 191 is input to the inverter 192. The output of the inverter 192 and the first reset signal RS1 are input to the NAND circuit 193. The output of the NAND circuit 193 is input to the inverter 194. In this example, the output of the NAND circuit 193 of the first extraction circuit 186-1 is used as the second signal reset 2. The switch 195 enters an ON state in the case where the output of the inverter 194 is H logic, and discharges the filter capacitor 128 of the filter unit 120.

In the case where the first reset signal RS1 is at L logic, the output of the NAND circuit 193 is fixed at the H logic. Therefore, the output of the inverter 194 (referred to as the filter reset signal FR1) is fixed to the L logic, and the switch 195 does not discharge the filter capacitor 128.

When the first reset signal RS1 transitions to H logic, the switch 190 enters an ON state, and the capacitor 188 is charged. As the voltage of the capacitor 188 increases, the input voltage to the inverter 191 decreases. In a period during which the input voltage to the inverter 191 is greater than the threshold voltage of the inverter 191, the output of the inverter 191 becomes L logic. Therefore, during the period, the output of the NAND circuit 193 becomes L logic, the filter capacitor 128 is discharged, and the filter period is reset. When the input voltage to the inverter 191 falls below the threshold voltage of the inverter 191, the output of the NAND circuit 193 becomes H logic, and the discharge of the filter capacitor 128 stops, and the filter capacitor 128 is recharged. Accordingly, after discharging the filter capacitor 128 for a certain period, it is possible to start the new filter period and extend the filter period.

FIG. 7B is a diagram representing the configuration example of the second extraction circuit 186-2. The second extraction circuit 186-2 has an architecture similar to the architecture of the first extraction circuit 186-1. However, the second reset signal RS2 is input to the switch 190. Further, the output of the inverter 194 of the second extraction circuit 186-2 is used as the filter reset signal FR2. In this example as well, when the second reset signal RS2 transitions to H logic, it is possible to discharge the filter capacitor 128 for a certain period and to start the new filter period.

FIG. 7C is a diagram representing the configuration example of the extraction circuit at the time of short-circuit release 197. The extraction circuit at the time of short-circuit release 197 has an architecture similar to that of the first extraction circuit 186-1. However, the short-circuit signal SCS is input to the switch 190. Further, the output of the inverter 194 in the extraction circuit at the time of short-circuit release 197 is used as the filter reset signal FR3. In this example as well, in the case where the short-circuit signal SCS transitions to H logic, it is possible to discharge the filter capacitor 128 only for a certain period and start the new filter period.

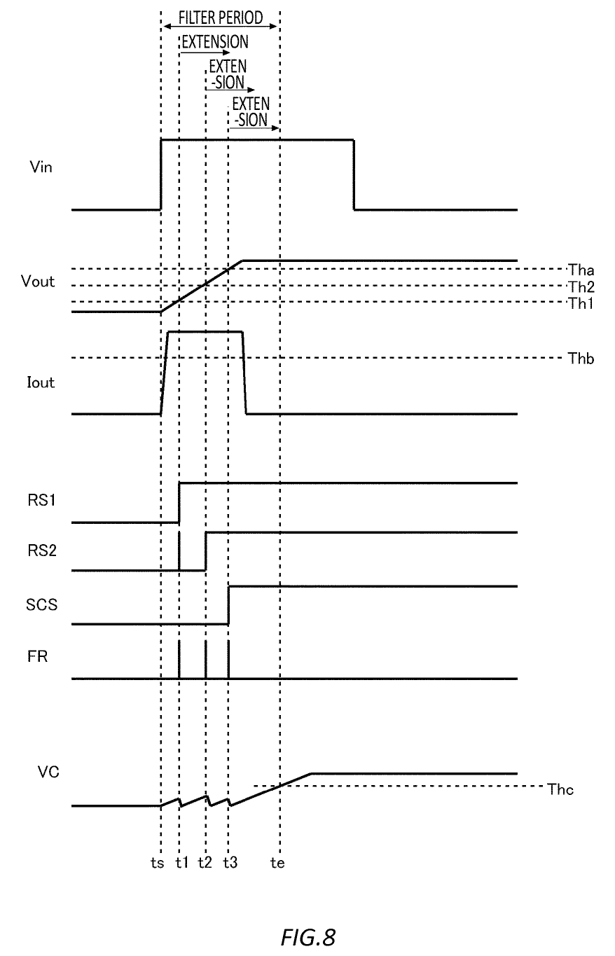

FIG. 8 is a diagram representing an operation example of the control circuit 100. The control signal Vin, the output voltage Vout, and the output current Iout in FIG. 8 are similar to the example shown in FIG. 4B. In FIG. 8, in addition to these waveforms, the waveforms of the first reset signal RS1, the second reset signal RS2, the short-circuit signal SCS, the filter reset signal FR, and the capacitor voltage VC are illustrated. The filter reset signal FR indicates the logical OR of each of the filter reset signal FR1, the filter reset signal FR2, and the filter reset signal FR3. The capacitor voltage VC is the voltage of the filter capacitor 128.

When the output voltage Vout exceeds the first threshold voltage Th1 at time t1, the first reset signal RS1 transitions to H logic and is maintained at H logic by the first latch unit 174. Further, by the second latch unit 180, the second reset signal RS2 indicates the H logic for an infinitesimal time. The first extraction circuit 186-1 generates the filter reset signal FR1 indicating H logic for a constant period of time in response to the first reset signal RS1. Similarly, the second extraction circuit 186-2 also generates the filter reset signal FR2. By these filter reset signals FR, the filter capacitor 128 is discharged for a fixed period of time. Therefore, the filter period is reset, and the new filter period starts.

The period change unit 150 further extends the filter period in the case where the output voltage Vout exceeds the second threshold voltage Th2 within the extended filter period. In this example, when the output voltage Vout exceeds the second threshold voltage Th2 at time t2, the second reset signal RS2 transitions to H logic and is maintained at H logic by the second latch unit 180. The second extraction circuit 186-2 generates the filter reset signal FR2 indicating H logic for a constant period of time in response to the second reset signal RS2. By the filter reset signal FR2, the filter capacitor 128 is discharged for a fixed period of time. Therefore, the filter period is reset, and the new filter period starts.

When the output voltage Vout exceeds the short-circuit determination voltage Tha at time t3, the short-circuit signal SCS transitions to the H logic by the short-circuit detection unit 112. The extraction circuit at the time of short-circuit release 197 generates the filter reset signal FR3 indicating the H logic for a constant period of time in response to the short-circuit signal SCS. By the filter reset signals FR3, the filter capacitor 128 is discharged for a fixed period of time. Therefore, the filter period is reset, and the new filter period starts.

When the capacitor voltage VC exceeds the filter threshold voltage Thc at time te, the filter period ends. By such a process, it is possible to appropriately extend the filter period.

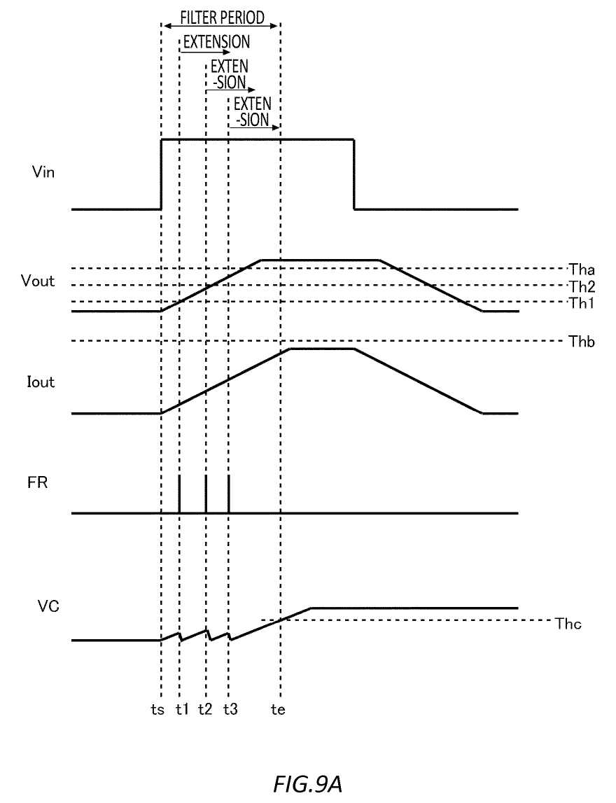

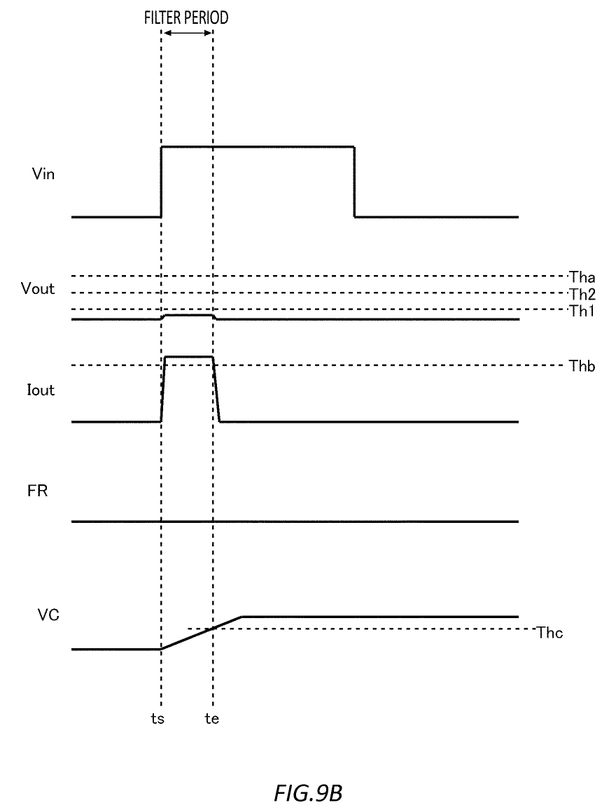

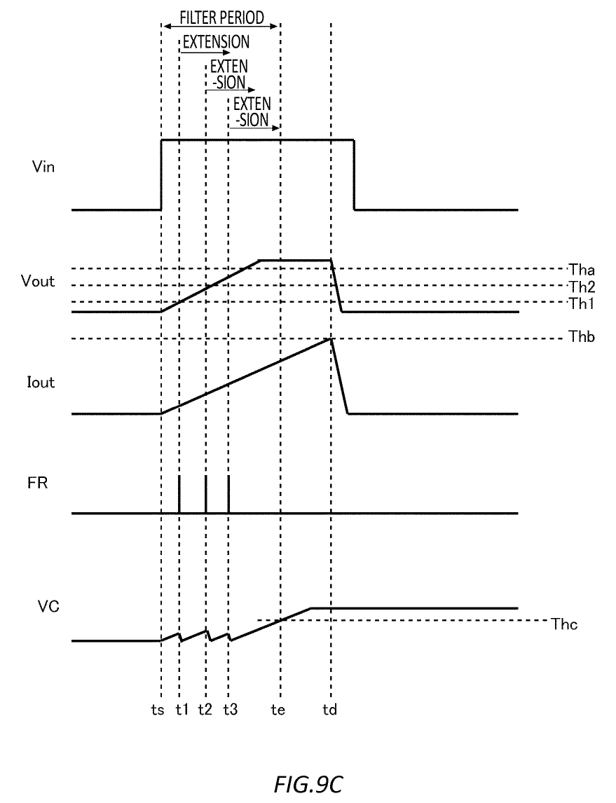

FIG. 9A is a timing chart representing another operation example of the control circuit 100. FIG. 9A represents each waveform in the case where the load circuit 200 with no load capacitor 204 is connected. In FIG. 9A and the like, the waveforms of the first reset signal RS1, the second reset signal RS2, and the short-circuit signal SCS are omitted.

In this example, the filter period is sequentially extended at the time t1, t2, and t3. At time te, the filter period ends, and determinations are made by the short-circuit detection unit 112 and the overcurrent detection unit 110. In this example, neither the short-circuit state nor the overcurrent is detected.

FIG. 9B is a timing chart representing another operation example of the control circuit 100. In FIG. 9B, the waveform in the short-circuit state is represented. In this example, the output voltage Vout does not exceed any of the threshold voltages. Therefore, the filter period has ended without being extended. When the filter period ends at the time te, and determinations are made by the short-circuit detection unit 112 and the overcurrent detection unit 110. In this example, since the output voltage Vout is smaller than the short-circuit determination voltage Tha at time te, it is detected by the short-circuit detection unit 112 that the short-circuit state exists. At time te, the overcurrent detection unit 110 may further detect that an overcurrent exists. As described above, according to the control circuit 100, in the case of the short-circuit state, the short-circuit state can be detected promptly without extending the filter period.

FIG. 9C is a timing chart representing another operation example of the control circuit 100. In FIG. 9C, each waveform in the case where the overcurrent state is detected after the elapse of the filter period is represented.

In this example, the filter period is sequentially extended at the time t1, t2, and t3. At time te, the filter period ends, and determinations are made by the short-circuit detection unit 112 and the overcurrent detection unit 110. In this example, the overcurrent is detected by the overcurrent detection unit 110 at time td. Accordingly, the output current Iout is shut down, and the switching device 106 and the load circuit 200 and the like can be protected.

In FIGS. 4A-9C, the threshold voltage generation unit 152 generates the two threshold voltages Th1 and Th2. In another example, it is also possible to generate the greater number of threshold voltages Th. The reset unit 170 may extend the filter period each time the output voltage Vout exceeds each of the threshold voltages Th. Each of the threshold voltages Th may be disposed at equal intervals between the short-circuit determination voltage Tha and the reference potential 0V, or may be disposed at unequal intervals.

For example, the region between the short-circuit determination voltage Tha and the reference potential 0V is divided equally into two, the high-voltage side region and the low-voltage side region. The number of the threshold voltages Th arranged in the high-voltage side region may be greater than, equal to, or less than the number of the threshold voltages Th arranged in the low-voltage side region. In a region where the threshold voltages Th are densely arranged, the resolution of the increase determination of the output voltage Vout can be enhanced, and the increase of the output voltage Vout can be accurately detected.

For example, at the time of startup of the semiconductor device 300, there may be a case where the upper limit value of the output current Iout is controlled to be low. In this case, the charging speed of the load capacitor 204 becomes slower, and the rising speed of the output voltage Vout becomes slower. By arranging a large number of the threshold voltages Th in the low-voltage side region, it is possible to accurately detect the increase in the output voltage Vout at the startup of the semiconductor device 300. The threshold voltage generation unit 152 may change the arrangement of the threshold voltage Th between the time of startup of the semiconductor device 300 and times other than the startup.

In each example described in the present specification, the period change unit 150 may adjust the length of the extension period for extending the filter period by adjusting the charging current for charging the filter capacitor 128. For example, the period change unit 150 may adjust the current value generated by the current source 122. The current source 122 may be the variable current source. The current source 122 may have a plurality of unit current sources provided in parallel. The current source 122 may adjust the charging current by controlling the number of unit current sources used to generate the charging current.

The period change unit 150 may adjust the length of the extension period for extending the filter period in response to the magnitude of the power supply voltage Vcc. The period change unit 150 may lengthen the extension period as the power supply voltage Vcc decreases. The period change unit 150 may shorten the extension period as the power supply voltage Vcc decreases.

The period change unit 150 may adjust the length of the extension period for extending the filter period based on the temperature of at least one of the switching device 106 or the load circuit 200. The period change unit 150 may shorten the extension period as the temperature of the load circuit 200 increases. Since the higher the temperature is, the higher the possibility that the element fails becomes, by shortening the extension period, it becomes easier to protect the switching device 106 or the load circuit 200. The period change unit 150 may shorten the extension period as the temperature of the switching device 106 increases. Since the higher the temperature is, the safe operating area of the switching device 106 becomes narrower, it becomes easier to protect the switching device 106 by shortening the extension period.

The control circuit 100 may detect at least one of the overheat state or the low voltage state in addition to an overcurrent state and a short-circuit state. The overheat state refers to the state in which the temperature of at least one of the control circuit 100 or the load circuit 200 exceeds a predetermined temperature. The low voltage state refers to a state in which a voltage applied to the power supply terminal Vcc is less than the predetermined voltage. The control circuit 100 may detect the overheat state and the low voltage state without applying the filter period.

While the embodiments of the present invention have been described, the technical scope of the present invention is not limited to the above-described embodiments. It is apparent to persons skilled in the art that various alterations or improvements can be added to the above-described embodiments. It is also apparent from the claims that the embodiments added with such alterations or improvements can be included in the technical scope of the present invention.

What is claimed is:

1. A control circuit that controls supply of electric power to a load circuit, comprising:
a switching device connected in series with the load circuit;
a short-circuit detection unit which detects whether the load circuit is in a short-circuit state and controls the switching device based on a detection result;
a filter unit which stops control of the switching device performed by the short-circuit detection unit from a turn-on of the switching device until a set filter period elapses; and
a period change unit which changes the filter period based on a state of at least one of the switching device or the load circuit.

2. The control circuit according to claim 1, wherein the period change unit determines, within the filter period, whether to extend the filter period based on a state of at least one of the switching device or the load circuit.

3. The control circuit according to claim 1, wherein the period change unit determines whether the load circuit is in a charging state in which a load capacitor included in the load circuit is being charged, based on the state of at least one of the switching device or the load circuit, and extends the filter period in a case of the charging state.

4. The control circuit according to claim 1, wherein the period change unit extends the filter period based on an output voltage applied to the load circuit.

5. The control circuit according to claim 4, wherein the period change unit extends the filter period in a case where the output voltage exceeds a first threshold voltage within the filter period.

6. The control circuit according to claim 4, wherein
the filter period with a certain length is set in the filter unit, and
the period change unit extends the filter period by starting a new filter period, which is equivalent to the filter period, during the filter period.

7. The control circuit according to claim 5, wherein
the short-circuit detection unit determines that the short-circuit state exists in a case where the output voltage does not exceed a short-circuit determination voltage after the filter period has elapsed, and
the first threshold voltage is lower than the short-circuit determination voltage.

8. The control circuit according to claim 7, wherein the period change unit further extends the filter period in a case where, within the filter period that is extended, the output voltage exceeds a second threshold voltage which is greater than the first threshold voltage and lower than the short-circuit determination voltage.

9. The control circuit according to claim 8, wherein the period change unit includes:
a threshold voltage generation unit which generates the second threshold voltage in a case where the output voltage exceeds the first threshold voltage after generating the first threshold voltage;
a voltage comparison unit which compares the output voltage with each threshold voltage generated by the threshold voltage generation unit; and
a reset unit which outputs a reset signal for resetting the filter period and starting a new filter period, which is equivalent to the filter period, in response to a comparison result in the voltage comparison unit.

10. The control circuit according to claim 9, wherein
the threshold voltage generation unit includes a first diode and a second diode connected in series,
the second diode is provided between the first diode and a reference potential, and
the threshold voltage generation unit includes a threshold switching unit which switches whether to connect a node between the first diode and the second diode to the reference potential in response to the reset signal.

11. The control circuit according to claim 9, wherein the threshold voltage generation unit outputs, to the voltage comparison unit, a voltage lower than the output voltage when the output voltage exceeds the short-circuit determination voltage.

12. The control circuit according to claim 9, wherein the reset unit includes:
a first latch unit that generates a first reset signal for resetting the filter period when the output voltage exceeds the first threshold voltage and maintains the first reset signal, and
a second latch unit that generates a second reset signal for resetting the filter period when the output voltage exceeds the second threshold voltage and maintains the second reset signal.

13. The control circuit according to claim 12, wherein the filter unit includes:
a filter capacitor,
a charging unit that charges the filter capacitor in response to the switching device being turned on. and
a period determination unit that determines that the filter period has ended in a case where, after the switching device is turned on, a voltage of the filter capacitor exceeds a filter threshold voltage, and wherein
the reset unit includes:
a first extraction circuit that extracts an electric charge of the filter capacitor for a preset period in response to the first reset signal, and
a second extraction circuit that extracts an electric charge of the filter capacitor for a preset period in response to the second reset signal.

14. The control circuit according to claim 13, wherein the reset unit further includes an extraction circuit at a time of short-circuit release that extracts an electric charge of the filter capacitor for a preset period in a case where the output voltage exceeds the short-circuit determination voltage.

15. The control circuit according to claim 13, wherein the period change unit adjusts a length by which the filter period is extended by adjusting a charging current for charging the filter capacitor.

16. The control circuit according to claim 1, wherein the period change unit adjusts a length by which the filter period is extended, based on a temperature of at least one of the switching device or the load circuit.

17. The control circuit according to claim 1, further comprising an overcurrent detection unit which detects whether an output current output to the load circuit is in an overcurrent state and controls the switching device based on a detection result, wherein
the filter unit stops control of the switching device performed by the overcurrent detection unit from a turn-on of the switching device until the filter period elapses.

18. A semiconductor device comprising:
the control circuit according to claim 1 and
the load circuit.

19. The semiconductor device according to claim 18, wherein the period change unit determines, within the filter period, whether to extend the filter period based on a state of at least one of the switching device or the load circuit.

20. The semiconductor device according to claim 18, wherein the period change unit determines whether the load circuit is in a charging state in which a load capacitor included in the load circuit is being charged, based on the state of at least one of the switching device or the load circuit, and extends the filter period in a case of the charging state.
